(19) United States
(12) Patent Application Publication
(10) Pub. No.: US 2018/0308729 A1
(43) Pub. Date: Oct. 25, 2018

(54) Hybrid substrate processing system for dry and wet process and substrate processing method thereof

(71) Applicants: ACN CO., LTD., Suwon-si, Gyeonggi-do (KR); ACM RESEARCH (SHANGHAI) INC., Shanghai (CN)

(72) Inventors: Dai Kyu CHOI, Gyeonggi-do (KR); Hui WANG, Shanghai (CN); Xi WANG, Shanghai (CN); Xiaoyan ZHANG, Shanghai (CN); Shena JIA, Shanghai (CN)

(21) Appl. No.: 15/738,055

(22) PCT Filed: May 27, 2016
(86) PCT No.: PCT/KR2016/005602

§ 371 Date: Dec. 19, 2017

(30) Foreign Application Priority Data
Jun. 19, 2015 (KR) 10-2015-0087219

(51) Int. Cl. H01L 21/67; H01L 21/687; H01L 21/677

(52) U.S. Cl. CPC H01L 21/67207; H01L 21/67173; H01L 21/67778; H01L 21/68707; H01L 21/67184

(57) ABSTRACT

The substrate can be selectively transferred by a vacuum or edge grip method according to the process characteristics, using a single substrate transfer robot equipped in the front end module. Additionally, after the process, the substrate can be loaded using the buffer chamber, for the cooling process and transfer of the substrate.

### TECHNICAL FIELD

The present invention is the hybrid substrate processing system for dry and wet process and the substrate processing method thereof, and more specifically, the hybrid substrate processing system for dry and wet process and the substrate processing method thereof which can prevent contamination of the substrate in a treatment system for processing semiconductor in wafer or substrate, while performing a wet process and dry process.

### BACKGROUND ART

Semiconductor processing for a substrate such as wafer or glass is conducted through numerous stages of semiconductor processing. Semiconductor is manufactured by forming a circuit pattern on a substrate via various processes, including photolithographic process. For example, the processes include deposition, etching, exposure process, development process, ashing process, cleaning processes and others. During these manufacturing processes, particles, organic pollutants, metal impurities are generated. These foreign substances cause defects in the substrate, acting as a factor that directly affects the yield of the semiconductor element. Therefore, a semiconductor manufacturing process essentially involves the cleaning process for removing foreign matter from the substrate.

In order to remove the photoresist patterned in the photolithographic process, two methods are used. The first method uses Piranha-based chemicals that combined Sulfuric acid (H2SO4) and hydrogen peroxide (H2O2) at a temperature of about 200° C. Cleaning with chemicals in high temperature causes damage on the surface of wafer and results in the loss of material. The second method is to perform washing using four equipment, including Soking using a single cleaner, Ashing using Asher, removal of wet photoresist material using Wet Bench, and cleaning using scrubber. Among these, ashing process uses a plasma dry etching, and plasma is used to selectively oxidize the photoresist material. Wet treatment process adds chemical solution on the wafer or substrate to remove the remaining photoresist material that is not removed by a plasma ashing process.

Such cleaning processes are conducted through the respective treatment facilities. Each process is conducted in different facilities, so the treated substrate is moved being exposed to the outside. Therefore, a problem arises that the treated substrate is contaminated.

In addition, the asking process and the wet process uses different equipment for treating the substrate or wafer, so it is required to build individual equipment for each process. Thus, this cleaning process is time consuming and complex, and increases the production costs.

### DISCLOSURE OF INVENTION

### Technical Problem

The object of the present invention is to provide a hybrid substrate processing system for wet and dry process, which can prevent contamination of the substrate because the dry treatment and the wet treatment of substrate can be carried out in a single platform, and the substrate processing method thereof.

A further object of the present invention is to provide a hybrid substrate processing system for dry process and wet process, which is capable of selectively transferring a substrate according to the dry process and wet process, using a substrate transfer robot that can transfer the substrate in a vacuum grip or edge grip, and the substrate processing method thereof.

Another object of the present invention is to provide a hybrid substrate processing system for wet process and dry process that can cool or load the substrate using a single buffer chamber, and the substrate processing method thereof.

### Solution to Problem

An aspect of the present invention for achieving the above-mentioned technical problems is related to the hybrid substrate processing system for wet process and dry process and the substrate processing method thereof. The hybrid substrate processing system for dry treatment and wet treatment of the present invention includes a front end module with the standby substrate; Atmospheric carrying module for loading/unloading substrate from the front end module; One or more dry processing module for dry processing of the substrate that is loaded from the Atmospheric carrying module; At least one wet processing module for wet processing of the aforesaid substrate; Buffer chamber in which the substrate treated cooling or loaded is waited; Atmospheric pressure substrate transfer robot that is equipped in the aforesaid Atmospheric carrying module, for transferring the substrate between the aforesaid buffer chamber and the said dry-processing module; and First substrate carrying module equipped with First substrate transfer robot which exchanges the substrate with the said atmospheric pressure substrate transfer robot and loads/unloads the substrate to the dry-processing module; and Second substrate carrying module equipped with Second substrate transfer robot which loads/unloads the substrate from the said buffer chamber, and loads/unloads the substrate to the said wet processing module.

And the said dry-processing module removes the carbide layer of photoresist formed on the said substrate surface during the ion implantation process, by being equipped with a plasma source, and performing the ashing process with respect to the said substrate.

In addition, the substrate processing system includes a controller that controls the operation of the dry and the wet processing modules, and controls the operation of the atmospheric pressure substrate transfer robot and the first and second substrate transfer robots for transfer of the substrate.

And the First substrate transfer robot includes a plurality of transfer arms; the rotation shaft for rotating the transfer arm; and the end effector that mounts the said substrate by being connected to the end of the transfer arm.

In addition, the dry-processing module includes a plurality of stages that are arranged on the pivoting path of the transfer arm of the first substrate transfer robot.

And the said buffer chamber includes the cooling buffer that is equipped with a plurality of cooling buffer slots for loading the substrate and cools the substrate; and a standby buffer equipped with a plurality of standby buffer slots for mounting the substrate.

Also the cooling buffer slot includes First cooling buffer slot equipped with a support member for supporting the substrate; And Second cooling buffer slot equipped with limit which is contacted with the said substrate.

And the cooling buffer or standby buffer includes a plurality of pusher units for the centering alignment of the substrate.

In addition, the atmospheric pressure substrate transfer robot includes a plurality of transfer arms installed to be movable linear; A plurality of edge grip end effectors installed in the First group among the said multiple transfer arms, for transferring the substrate in the edge grip method; A plurality of vacuum grip end effector installed in the Second group among the said multiple transfer arms, for transferring the substrate in the vacuum grip method.

And the wet processing module includes one or more spray nozzles for spraying de-ionized water or cleaning agent in a gas or vapor.

The substrate processing method using a hybrid substrate processing system for the dry treatment and wet treatment of the present invention includes the stage of unloading a substrate from the front end module and transferring it to the First substrate carrying module by using the atmospheric pressure substrate transfer robot; the stage of loading the substrate to the said dry process module by using first substrate transfer robot of the said First substrate carrying module and performing the dry process; the stage of delivering the dry-processed substrate from the dry-processing module to the Atmospheric carrying robot using first substrate transfer robot; the stage of transferring the substrate to a cooling chamber in the buffer chamber with the Atmospheric carrying robot; the stage of unloading the substrate from the cooling chamber using the Atmospheric carrying robot and transferring the substrate to the front end module.

And it further includes the stage of unloading the substrate from the cooling chamber using second substrate transfer robot of Second substrate carrying module; the stage of loading the substrate using second substrate transfer robot to the wet processing module for wet processing; the stage of loading the liquid-treated substrate in the wet processing module to the standby chamber of the buffer chamber using second substrate transfer robot.

In addition, it includes the stage of unloading the substrate from the standby chamber by using the Atmospheric carrying robot and transferring the substrate to the First substrate carrying module; the stage of loading the substrate to the dry processing module using first substrate transfer robot for the dry processing; the stage of transferring the dry-processed substrates to the atmospheric pressure carrying robot using the first substrate transferring robot; the stage of loading the substrate to the cooling chamber of the buffer chamber with the Atmospheric carrying robot; and the stage of unloading the substrate from the cooling chamber and transferring the substrate to the front end module using the Atmospheric carrying robot.

The substrate processing method using a hybrid substrate processing system for the dry treatment and wet treatment of the present invention comprises the step of unloading the substrate from the front end module using the atmospheric pressure substrate transfer robot and loading to the standby buffer of the buffer chamber; step of unloading the substrate from the waiting buffer using second substrate transfer robot of Second substrate carrying module; step of wet processing after loading the substrate to a wet processing module using second substrate transfer robot; the step of loading the wet-processed substrate from the wet processing module to the standby buffer using second substrate transfer robot; and the step of unloading the substrate from the standby buffer using the atmospheric pressure substrate transfer robot and transferring it to the front end module.

Further, it includes the stage of unloading the substrate from the standby buffer by using the Atmospheric carrying robot and transferring the substrate to the first substrate transfer robot of the First substrate carrying module; the stage of dry processing by loading substrate to the dry-processing module using first substrate transfer robot; the stage of delivering the dry-processed in the dry-processing module to the Atmospheric carrying robot using the first substrate transfer robot; the stage of transferring the substrate to a cooling chamber of the buffer chamber with the Atmospheric carrying robot; and the stage of using the Atmospheric carrying robot and unloading the substrate from the cooling chamber and transferring it to the front end module.

And it further comprises the step of unloading the substrate from the cooling chamber by the second substrate transfer robot and transferring it to the wet processing module for the wet treatment; step of transferring the wet-processed substrate to the standby buffer of the buffer chamber using second substrate transfer robot; and the step of using the Atmospheric carrying robot and unloading the substrate from the standby chamber and transferring it to the front end modules.

### Advantageous Effects of Invention

According to the substrate processing method of using a hybrid substrate processing system for the dry process and the wet process of the present invention, both the dry process and the wet process are performed in one platform, so that the substrate is not discharged to the outside, making it possible to prevent the substrate from being contaminated. In addition, the substrate can be selectively transferred by a vacuum or edge grip method according to the process characteristics, using a single substrate transfer robot equipped in the front end module. Additionally, after the process, the substrate can be loaded using the buffer chamber, for the cooling process and transfer of the substrate.

### BRIEF DESCRIPTION OF DRAWINGS

FIG. 1 is a schematic view illustrating the structure of a hybrid substrate processing system according to the first preferred embodiment of the present invention.

FIG. 2 is a view illustrating the dry processing module, equipped with first substrate transfer robot.

FIG. 3 is a view illustrating the wet processing module of the stack structure.

FIG. 4 is a perspective view showing the whole buffer chamber.

FIGS. 5 and 6 are views illustrating the cooling buffer slot and a pusher unit equipped within the cooling buffer.

FIG. 7 is a cross-sectional view showing the path structure of cooling water of the cooling buffer.

FIG. 8 is a view illustrating the exhaust structure of a cooling buffer.

FIG. 9 is a view illustrating the buffer slot equipped within the standby buffer.

FIG. 10 is a perspective view showing an atmospheric pressure substrate transfer robot.

FIG. 11 is a view showing the side of the atmospheric pressure substrate transfer robot.

FIG. 12 is a view showing an edge grip-end effector.

FIG. 13 is a view illustrating a vacuum grip-end effector.

FIGS. 14 and 15 are views illustrating the state in which the atmospheric pressure substrate transfer robot is moved.

FIGS. 16 and 17 are views illustrating the state in which the atmospheric pressure substrate transfer robot is rotated.

FIGS. 18 and 19 are views illustrating the moving path of the substrate.

FIG. 20 is a flowchart illustrating the dry-wet processing method of substrate using the substrate processing system of the present invention.

FIG. 21 is a flowchart illustrating the wet-dry processing method of substrate using the substrate processing system of the present invention.

FIG. 22 is a flowchart illustrating the dry-wet-dry processing method of substrate using the substrate processing system of the present invention.

FIG. 23 is a flowchart illustrating the wet-dry-wet processing method of substrate using the substrate processing system of the present invention.

FIG. 24 is a flowchart illustrating the dry processing method of substrate using the substrate processing system of the present invention.

FIG. 25 is a flowchart illustrating the wet processing method of substrate using the substrate processing system of the present invention.

FIG. 26 is a schematic view illustrating the structure of the hybrid substrate processing system according to the second preferred embodiment of the present invention.

### BEST MODE FOR CARRYING OUT THE INVENTION

Preferred embodiments of the present invention will be described with reference to the accompanying drawings in order to fully understand the present invention. Embodiments of the present invention may be modified in various forms, and the scope of the invention should not be construed as limited to the embodiments described in detail below. This example is being provided in order to explain the invention more fully to those with average knowledge in the relevant industry. Therefore, the shape of the elements in the figures may be expressed exaggeratedly to emphasize more specific description. It is to be noted that the same configuration in each drawing is in some cases illustrated by the same reference numerals. Detailed description of known functions and configurations which is deemed to unnecessarily obscure the main point of the present invention will be omitted.

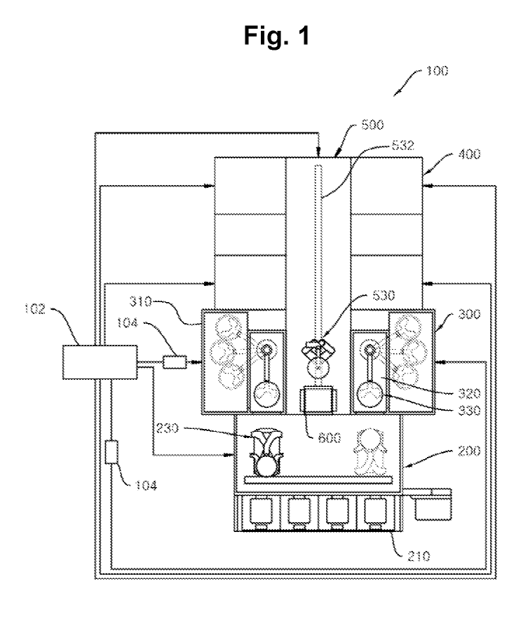

FIG. 1 is a schematic view illustrating the schematic structure of a hybrid substrate processing system according to a preferred embodiment of the present invention.

Referring to FIG. 1, the substrate processing system according to the invention (100) consists of the front end module, Atmospheric pressure substrate carrying module (200), Dry processing module (300), wet processing module (400), First substrate carrying module (320), Second substrate carrying module (500), buffer chamber (600), and a control unit (102).

Equipment Front End Module is installed in the front of the substrate processing system (100), and has a configuration for providing the substrate (106) to the processing chambers within the substrate process system (100). The front end module includes one or more cassettes (210) loaded with substrate (106).

Atmospheric pressure substrate carrying module (200) is equipped with the atmospheric pressure substrate transfer robot (230) as a substrate transfer module for loading/unloading the substrate (106) from cassette (210) under the conditions of atmospheric pressure being connected to the front end module. Atmospheric pressure substrate transfer robot (230) moves along the rails (240) and loads/unloads the substrate (106) from the cassette (210) of the front end module, and exchange the substrate between dry processing module (300) and buffer chamber (600).

Dry processing module (300) proceeds the plasma ashing process by being provided with a plasma source. Dry processing module (300) removes the carbonated layer of photoresist formed on the surface of the substrate (106) during the ion implantation process Dry processing module (300) consists of dry processing chamber (310) equipped with a stage (320) for processing a plurality of substrates (106) inside, and the First substrate carrying module (320) for loading/unloading the substrate (106) to the dry-processing chamber (310). First substrate carrying module (320) and dry-processing chamber (310) is connected with the vacuum pump (104), and it maintains the inside of drying process chamber (310) and First substrate carrying module (320) as vacuum when the dry ashing process is performed. First substrate carrying module (320) is equipped with the substrate transfer robot (330) to exchange the substrate (106) with the atmospheric pressure substrate transfer robot (230). In the present invention, two dry processing modules (300) are connected with the atmospheric pressure substrate carrying module (200).

Wet processing module (400) performs wet chemical cleaning process to the substrate (106) at atmospheric pressure conditions. Wet processing module (400) has a single station, and removes a foreign substance on the surface of the substrate (106) through the wet chemical cleaning process. Wet processing module (400) is equipped with at least one injection nozzle on the surface of substrate (106) for injecting the chemicals (detergent) for cleaning of the surface. The spray nozzle injects chemicals in the central region of the substrate (106), and the chemical is distributed evenly on the substrate by the rotation of the substrate (106). Wet processing module (400) may consist of the wet processing chamber performing a wet process that has one level, or that has a stacked configuration with two or three levels. Wet treatment process in the wet processing module (400) is conducted at atmospheric pressure.

Second substrate carrying module (500) is equipped with the wet processing module (400) on the both sides, and loads/unloads the substrate (106) to the wet processing module (400). Second substrate carrying module (500) includes second substrate transfer robot (530) that moves along the rail (532) to transfer the substrate before wet treatment (106) and the wet-treated substrate. Second substrate transfer robot (530) is equipped with a plurality of transfer arms, and has the structure for loading/unloading the substrate (106) to the wet processing module (400) that is installed on the both sides of the Second substrate carrying module (500). A plurality of transfer arms are formed as a joint structure, and the number of transfer arms is adjustable according to the number of substrate (406) to be treated in the wet processing module (400).

Second substrate transfer robot (530) loads/unloads the substrate (106) to the plurality of wet processing module (400) in one movement. In addition, second substrate transfer robot (530) can move up and down to load/unload the substrate (106) to the wet processing module (400) of the laminated structure. The substrate processing system (100) in the first preferred embodiment transfers the substrate (106) to a plurality of wet processing modules (400) by using a Second substrate transfer module (500).

A buffer chamber (600) has the configuration for exchanging the substrate (106), being equipped between the dry processing module (300) and wet-processing module (400), and it is connected with Second substrate carrying module (500) and atmospheric pressure substrate carrying module (200). A buffer chamber (600) is loaded with the substrate (106) delivered from the atmospheric pressure substrate transfer robot (230) of the front end module (200), and the substrate (106) delivered from second substrate transfer robot (530). A buffer chamber (600) consists of a cooling buffer for cooling the substrate (106) and a buffer chamber in which the substrate is loaded and waits. The structure of the buffer will be described in detail below.

Controller (102) controls the overall operation of the substrate processing system (100). Controller (102) controls respective modules to maintain the atmospheric pressure or vacuum state for the treatment or transfer of substrate. When performing a dry process, the controller (102) sends a control signal to operate the vacuum pump (104) and maintains the dry processing module (300) in a vacuum state. When unloading the dry treated substrate (106), the controller (102) sends a control signal so that First substrate carrying module (320) becomes in the state of atmospheric pressure. First substrate carrying module (320) is in the atmospheric pressure conditions when loading/unloading the substrate (106), and in the vacuum state in the dry treatment process.

The substrate processing system (100) according to the present invention can prevent the substrate (106) from being contaminated, because both the dry process and the wet process are performed in one platform, without discharging the substrate (106) to the outside. In addition, using a buffer chamber (600), it can load the substrate for the cooling process after process and the transfer of the substrate.

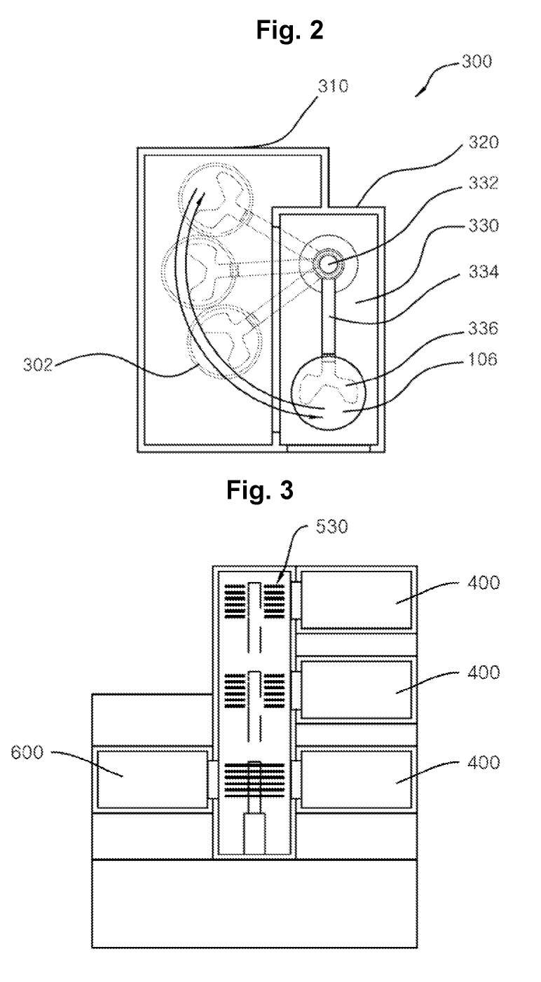

FIG. 2 is a drawing illustrating the dry processing module equipped with first substrate transfer robot, and FIG. 3 is a drawing illustrating a wet processing module of the stack structure.

Referring to FIG. 2, dry processing module (300) consists of dry processing chamber (310) provided with the Stage (302) and the first substrate carrying module (320). Dry processing chamber (310) is equipped with a plurality of stages (302) inside, to handle multiple substrates (106) at the same time. The substrate (106) loaded to dry processing chamber (310) through the first substrate carrying module (320) is treated dry processing.

First substrate carrying module (320) has the configuration for a dry processing chamber (310) and is equipped with first substrate transfer robot (330). First substrate transfer robot (330) is composed of a plurality of transfer arms (334) that rotate around the drive shaft (332). A plurality of transfer arms (334) rotate around the drive shaft (332) in an arc shape. In the end of the transfer arm (334), the end effector (336) is equipped for supporting the substrate (116). The number of transfer arms (334) correspond to the number of substrates (106) that can be processed at a time in the dry processing chamber (310). In addition, as stages (302) are aligned on the assembling path of the transfer arm (334), the transfer arms (334) load or unload the substrate (106) at once to the stage (302) while rotating.

Referring to FIG. 3, wet processing module (400) can form the wet process chamber by laminating it at two or more levels. By forming the wet processing module (400) in the stacked structure with at least two levels, it can handle a plurality of substrate (106) at a time, and also reduce the area occupied. In the present invention, the wet processing module (400) is formed at three levels, and 12 substrates can be processed at the same time. In order to send the substrate (106) to the wet processing module (400) of each layer, the lifting height of second substrate transfer robot (530) can be adjusted according to each number of level.

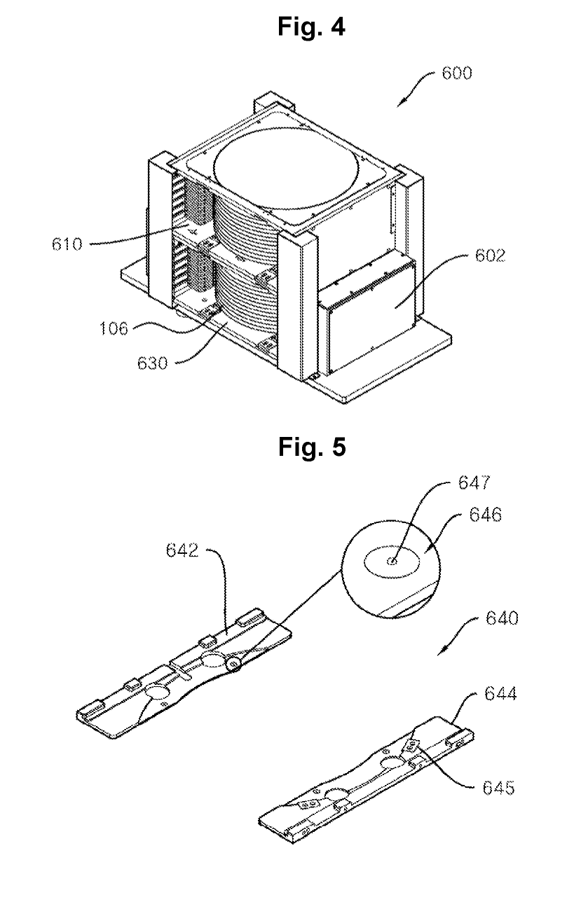

FIG. 4 is a perspective view showing the whole of the buffer chamber.

Referring to FIG. 4, a buffer chamber (600) consists of the cooling buffer in the lower part (630) and the standby buffer in the upper part (620). Cooling buffer (630) is loaded with dry-treated substrate (106) from the dry processing module (300), and it cools down the dry-treated substrate (106), in particular, the substrate with high-temperature (106) after the ashing process. The dry-treated substrate (106) from the dry processing module (300) is unloaded by first substrate transfer robot (330) and delivered to the atmospheric pressure substrate transfer robot (230), and loaded by atmospheric pressure substrate transfer robot (230) to the cooling buffer (630). The cooled substrate (106) from the cooling buffer (630) is unloaded by second substrate transfer robot (530) or atmospheric pressure substrate transfer robot (230). On the both sides of cooling buffer (630), the exhaust box (602) is equipped to discharge the inside air of the cooling buffer (630). The exhaust box (602) is made of transparent material, and one can confirm the internal structure of cooling buffer (630) through naked eyes. Cooling buffer (630) can be utilized as an standby buffer, by loading the substrate (106) after stopping the function of cooling process of substrate (106).

Standby buffer (610) is equipped to the upper part of the cooling buffer (630), and is loaded with the substrate of room temperature or low temperature (106) for wet processing in the wet processing modules (400) or to be provided to wet processing module (400). Wet-processed substrate from the wet processing module (400) is carried by second substrate transfer robot (530) and loaded to the standby buffer (610), and again unloaded by atmospheric pressure substrate transfer robot (230). Cooling buffer (630) and standby buffer (620) are equipped with a sensor (not shown) to determine the presence or absence of the substrate loaded therein.

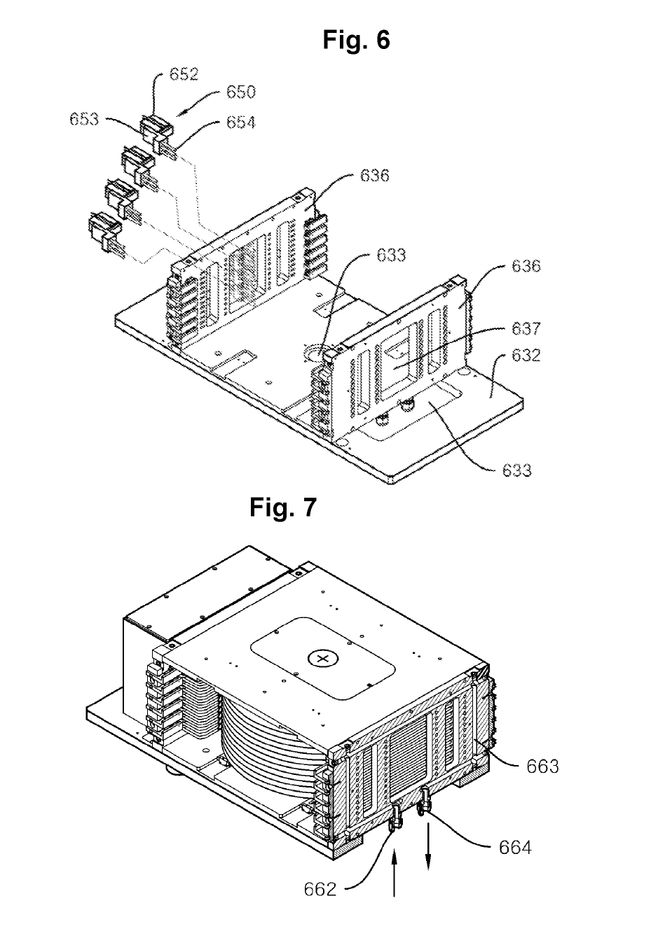

FIGS. 5 and 6 are views illustrating a cooling buffer slot, and a pusher unit equipped inside a cooling buffer.

Referring to FIG. 5, cooling buffer (630) is equipped with a plurality of cooling buffer slots (640) as a configuration for supporting the substrate (106). A plurality of cooling buffer slots (640) are installed with a gap that the substrate (106) can be mounted. Cooling buffer slot (640) consists of first and second cooling buffer slots (622, 624), and First and second Cooling buffer slots (622, 624) are installed on the inner side of the cooling buffer (630) facing each other. First cooling buffer slot (622) is equipped with one or more bumps (647) that are in contact with the bottom of the dry-processed substrate (106). Bump (647) is formed on the top of the support member (646) that is inserted into first cooling buffer slot (622). Bump (647) contacts with the minimum area of the substrate (106) which is formed in a round shape and mounted. Therefore, this prevents contamination of the back side of the dry-treated substrate (106), and because it contacts with only a minimal portion of the substrate (106), the entire substrate (106) can be cooled evenly. In addition; the bumps (647) are formed in a round shape and formed of material whose hardness is less than substrate (106), (E.g., PEEK, Polyetheretherketone), so when the substrate (106) is aligned by a pusher unit which will be described later, it prevents scratches from occurring on the back side of the substrate (106).

Second cooling buffer slot (624) is equipped with at least one Limit (645) so that the side of the mounted substrate (106) is in contact therewith. When performing a centering operation for the alignment of the substrate (106), when the side of substrate (106) placed on first and second cooling buffer slots (642, 644) contacts with Limit (645), the sorting operation is completed.

Referring to FIG. 6, substrate (106) loaded to the cooling buffer (630) is transferred by second substrate transfer robot (530) to the wet processing module (400). At this time, Second substrate transfer robot (530) transfers the substrate (106) by grabbing the edge of it. Therefore, the substrate (106) should be correctly aligned so that it can be transferred.

On the side (636) of cooling buffer (630), a plurality of pusher units (650) are equipped for the centering of substrate (106) placed on first and second cooling buffer slots (622, 624). Pusher unit (650) is equipped with a push bar (654) for applying force to the side of substrate (106), and first body part (652) and a push bar (654) formed of a ceramic (654). In addition, it also consists of second body part (653), which is installed to move by sliding to the first body part (652). In the pusher unit (650), the push bar (654) is inserted and installed into the cooling buffer (630), in order to apply a pressing force to the side of substrate (106) placed on the cooling buffer slot (640). The side of substrate (106) placed on the cooling slot buffer (640) is moved and arranged at the centering by the push bar (654) of the second body part (653) that is pushed by sliding by the driving means (Not shown).

The number of Push bar (654) is same as the number of substrate (106) that is treated by a single step of processing at dry processing module (300). In the present invention, the dry processing module (300) is equipped with three stages (302) and subjects three pieces of substrate (106) to dry processing at the same time. Thereby, forming the push bar (654) in the amount of three units, it subjects three pieces of substrate processed in the dry processing module (300) to the centering at the same time. Pusher unit (650) can be equipped in the standby buffer (610). The substrate (106) stacked on standby buffer (610) can be carried out centering alignment through the pusher unit (650) for an edge grip.

FIG. 7 is a cross-sectional view showing the path structure of a cooling water buffer.

Referring to FIG. 7, cooling buffer (630) is equipped with the cooling water inlet (662) and the cooling water outlet (664) on the bottom surface (632), and inside of the side surface (636), cooling water path (663) in which cooling water moves is formed. Cooling water supplied from cooling water sources (Not shown) is injected through a cooling water inlet (662), and moves along the cooling path (663) and is discharged to water outlet (664). By cooling water moving along cooling path (663), the temperature inside the cooling buffer (63) and the substrate (106) stacked on the cooling buffer (630) is lowered.

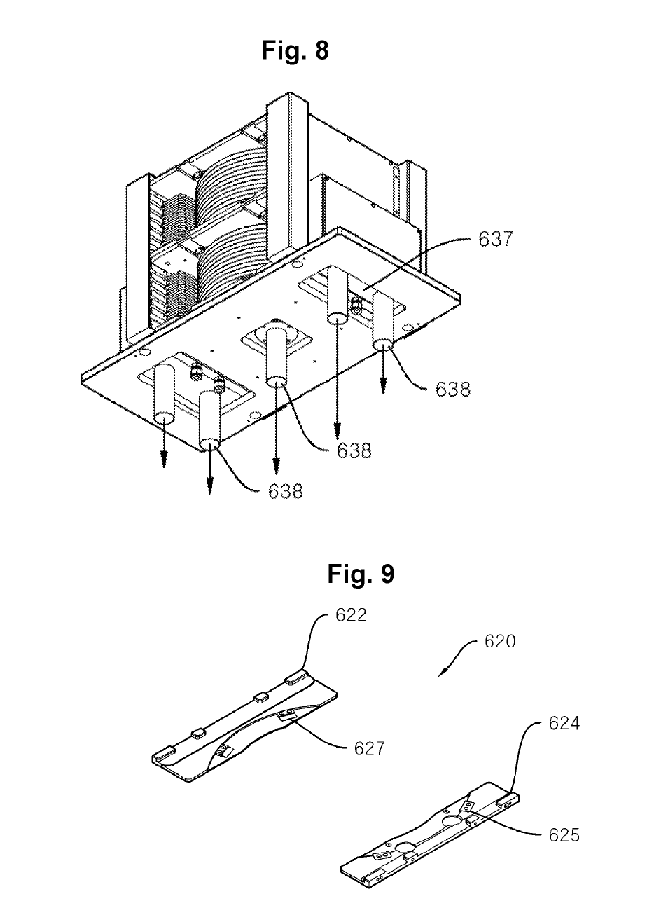

FIG. 8 is a view illustrating an exhaust structure of a cooling buffer.

Referring to FIG. 8, the bottom surface (632) of cooling buffer (630) is equipped with the openings (633, 637). Formed openings (633,637) are equipped with a plurality of exhaust ports (638) for discharging the air in the cooling buffer (630). A plurality of vents (638) are provided in the exhaust box (602), and the exhaust box (602) is provided on the side of cooling buffer (630) so that vent (638) is inserted into openings (633, 637).

Cooling buffer (630) is opened on both sides, and the air inflow from the opened both sides are discharged through vents formed on the bottom surface (632), and forms an air flow in the cooling buffer (630). Therefore, substrate (106) may be cooled by a flow of air in the cooling buffer (630).

FIG. 9 is a view illustrating a buffer slot provided inside the standby buffer.

Referring to FIG. 9, the standby buffer (610) is equipped with a plurality of standby buffer slots (620) composed of first and second standby buffer slots (622, 624). A plurality of standby buffer slot (620) is provided with a gap that substrate (106) can be mounted. On the upper surface of first standby buffer slot (622), one or more substrate loader (627) is equipped, and on the upper surface of second standby buffer slot (624), at least one limit (625) is equipped. Substrate (106) loaded on the standby buffer (610) is seated so that the back of it is in contact with the substrate loader (627), and the side is in contact with limit (625). A substrate loader (627) and limit (625) is formed of ceramic.

When a buffer chamber (600) in accordance with the present invention is used, cooling buffer (620) and standby buffer (610) for cooling process can be performed in a chamber, preventing the substrate (106) from being exposed to the outside and being contaminated. In addition, substrate cooling and loading can be accomplished at the same time in one chamber.

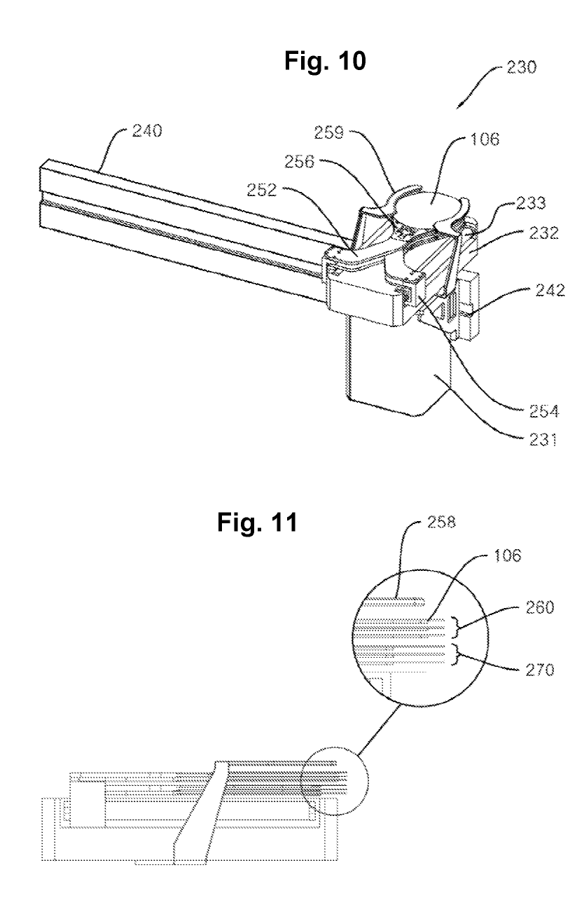

FIG. 10 is a perspective view showing the atmospheric pressure substrate transfer robot, and FIG. 11 is a side view showing an atmospheric substrate transfer robot.

Referring to FIG. 10, atmospheric pressure substrate transfer robot (230) is installed on the first and second body parts (231, 232) that move along the rails (240) and second body parts (232), thus it is composed of a plurality of first and second transfer arms (252,257) for transferring substrate (106).

Rail (240) is installed on the path on which the substrate can be transferred to dry processing module (300) connected to the atmospheric pressure substrate carrying module (200). On tracks (242) formed on rail (240), first body parts (231) are installed, and moved along the track (242). On the end of each of a plurality of first and second transfer arms (252, 257), moving guides (254) are installed, and moving guides (254) move along the guide bar (233) equipped on the side of second body parts (232). Thus, by the movement of moving guide (254), multiple number of first and second transfer arms (252, 257) moves straight. At this time, first and second transfer arms (252, 257) move straight in the direction of the dry processing module (300) or cassette (210).

In the end of first transfer arm (252), the edge grip end effector (256) on which the substrate (106) is seated is equipped. Edge grip end effector (256) has the structure that it can transfer substrate by gripping the edge of substrate (106) in the form of y. In the end of second transfer arm (257), vacuum grip end effectors (258) is equipped, on which the board (106) is seated. Vacuum grip end effector (258) has the structure of absorbing the substrate (106) by vacuum methods and transferring it. Atmospheric pressure substrate transfer robot (230) is equipped with the substrate position sensor (259) that can determine if substrate (106) is properly seated.

Referring to FIG. 11, in the present invention, first and second transfer arm (252, 257) is provided in 3 units, respectively. Located at the top, three transfer arms are equipped with edge grip end effectors (256) and forms the edge grip end effector (260) that transfers substrate (106) by holding the edge of substrate (106), and three transfer arms located in the lower part are equipped with vacuum grip end effector (258), forming the vacuum grip part (270) for holding a substrate with vacuum and transferring it.

In Edge grip part (260), one first transfer arm (252) is equipped with two edge grip end effectors (256), and another first transfer arm (252) is equipped with one edge grip end effector (256). Therefore, when transferring 1-3 pieces of substrates (106), it is possible to selectively choose the transfer arm for transferring the substrate. In vacuum grip (270) one second transfer arm (257) is equipped with two vacuum grip end effectors (258), and another second transfer arm (257) is equipped with one vacuum grip end effector (258). Edge grip part (260) or vacuum grip part (270) is selectively driven when required by the process in response to the control signal of a control unit (102).

Atmospheric pressure substrate transfer robot (230) absorbs substrate (106) by vacuum by driving second transfer arm (257), when unloading substrate (106) from cassettes (210), when delivering the substrate (106) to first substrate transfer robot (330) of the dry processing module (300), and when transferring substrate (106) to cooling buffer (620). Adsorbing the substrate by means of vacuum can transfer the substrate in a stable and high-speed way.

Since the substrate (106) before and after the wet processing should not be polluted on the back side, the substrate (106) is transferred by edge grip method when loading/unloading the substrate (106). Therefore, second substrate transfer robot (530) is a substrate transfer robot in the edge grip way. The substrate (106) stacked on the standby chamber (610) after wet processing or substrate (106) for wet treatment is transferred by driving first transfer arm (252) and holding the edge portion of the substrate (106). Therefore, the substrate (106) can be prevented from the contamination of its back side. In addition, substrate (106) can be transferred accurately.

Dry-treated substrate (106) is loaded in the cooling buffer (630) through the vacuum grip end effector (258) of the atmospheric pressure substrate transfer robot (230). Loaded board (106) is aligned to the center by Pusher unit (650) described above. The aligned substrate (106) is provided to the wet processing module (400) through the edge grip method by second substrate transfer robot (530). Wet-treated substrate (106) from the wet processing module (400) is transferred by edge grip method and loaded on the waiting buffer (610). Substrate (106) stacked in waiting buffer (610) is unloaded to the front end module via edge grip end effector (256) of the atmospheric pressure substrate transfer robot (230).

The present invention disclosed the structure in which the transfer arm of atmospheric pressure substrate transfer robot (230) is moved in the linear form, but it does not limit the structure of the transfer arm, and a transfer arm can be formed into various shapes such as joint shape.

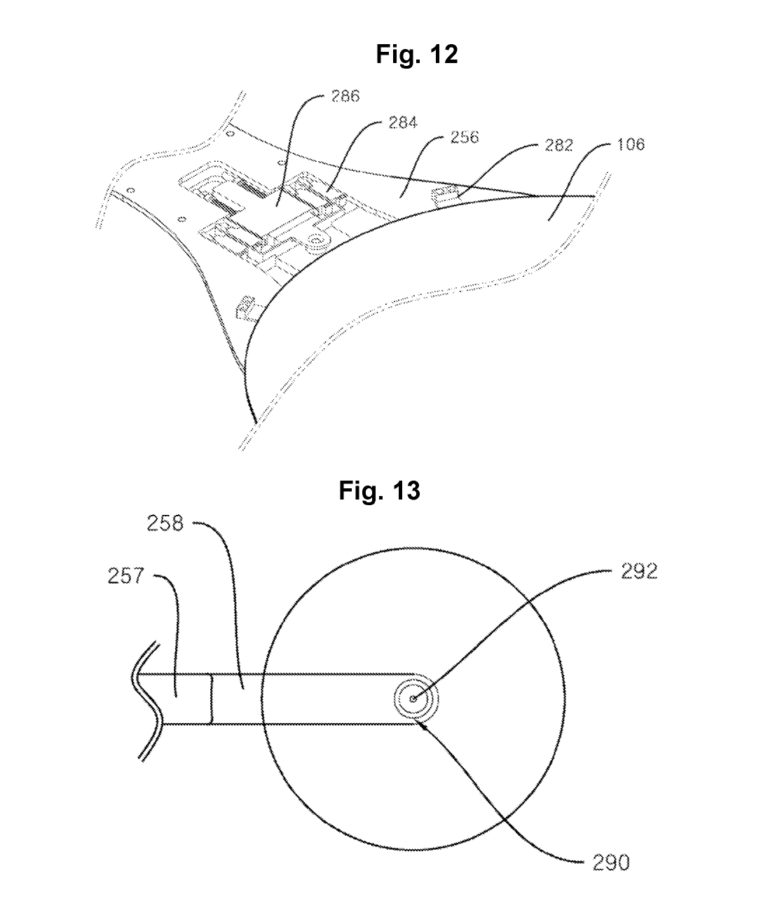

FIG. 12 is a view showing an edge grip end effector, and FIG. 13 is a drawing illustrating a vacuum grip end effector.

Referring to FIG. 12, edge grip end effector (256) is equipped with substrate loader (282) on which substrate (106) is seated. In the center of Edge grip end effector (256), pusher unit (286) for centering alignment of the substrate (106) is provided. Pusher unit (286) aligns the substrate (106) by applying a force pushing the substrate (106). On the both sides of Pusher unit (286), photo sensor (284) is equipped.

Referring to FIG. 13, on the upper surface of vacuum grip end effector (258), a vacuum pad (290) for supporting the substrate (106) is equipped. The vacuum pad (290) is equipped with vacuum holes (292) in the concave form in the center. When the substrate (106) is seated in vacuum pads (290), the air is drawn through the vacuum hole (292), and the substrate (106) is adsorbed to the vacuum pads (290), Vacuum Pads (290) are formed of composite material of plastics, having stronger durability and prolonged life expectancy.

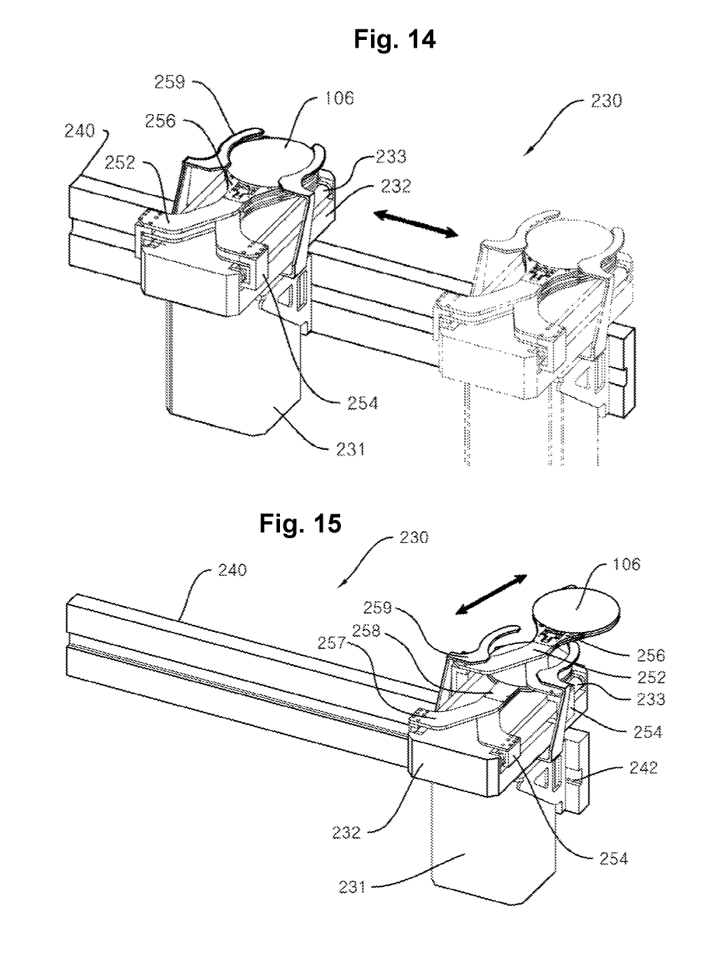

FIGS. 14 and 15 are drawings illustrating a state in which the atmospheric pressure substrate transfer robot is moved.

Referring to FIGS. 14 and 15, atmospheric pressure substrate transfer robot (230) moves along the rails (240). Moving along the rail (240), atmospheric pressure substrate transfer robot (230) exchanges the substrate (106) with first substrate transfer robot (330) of the dry processing module (300) and transfers the substrate (106) to the exchange buffer chamber (600). In addition, First transfer arm (252) and second transfer arm (257) of the atmospheric pressure substrate transfer robot (230) are moved back and forth in accordance with the control signal to load/unload the substrate (106) in the direction of the dry processing module (300) or cassette (210).

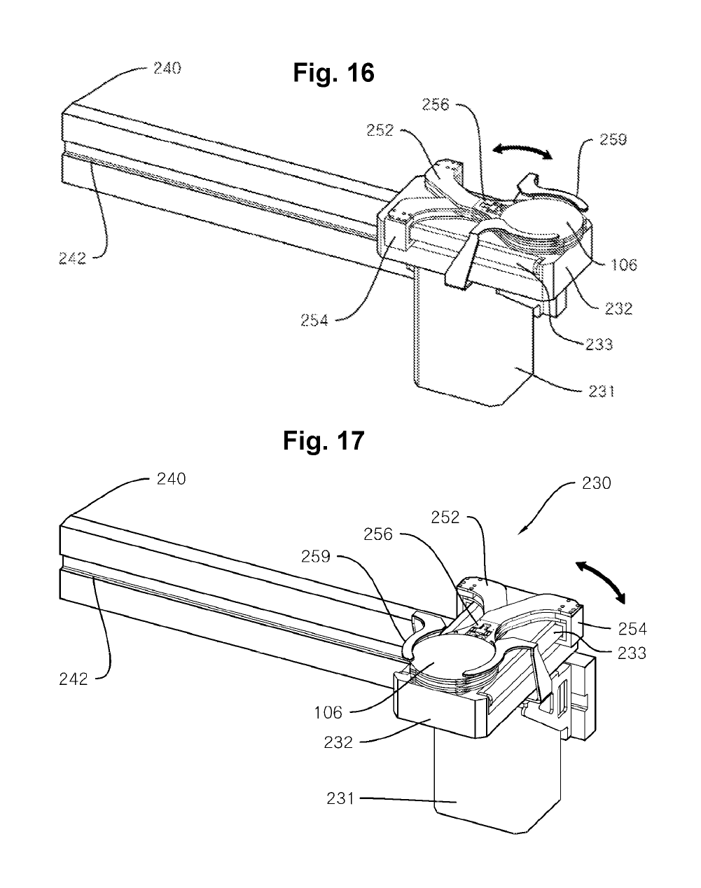

FIGS. 16 and 17 are drawings showing a state in which atmospheric pressure substrate transfer robot is rotated.

Referring to FIGS. 16 And 17, atmospheric pressure substrate transfer robot (230) is rotated to load/unload the substrate (106) in the direction of dry processing module (300) or cassette (210).

Atmospheric pressure substrate transfer robot (230) is rotated, so that the transfer arms (252, 257) advance forward and deliver the substrate (106) to the module to which it intends to transfer the substrate (160). Atmospheric pressure substrate transfer robot (230) is controlled and rotated in accordance with the control signal of the control unit (104), so that first and second transfer arms (252, 257) are headed to the direction of module to which it intends to deliver the substrate. When the rotation is complete, the control unit (104), if it requires the edge grip, generates a control signal so that first transfer arm (252) advances forward, and if it requires vacuum grip, generates a control signal so that second transfer arm (257) advances forward.

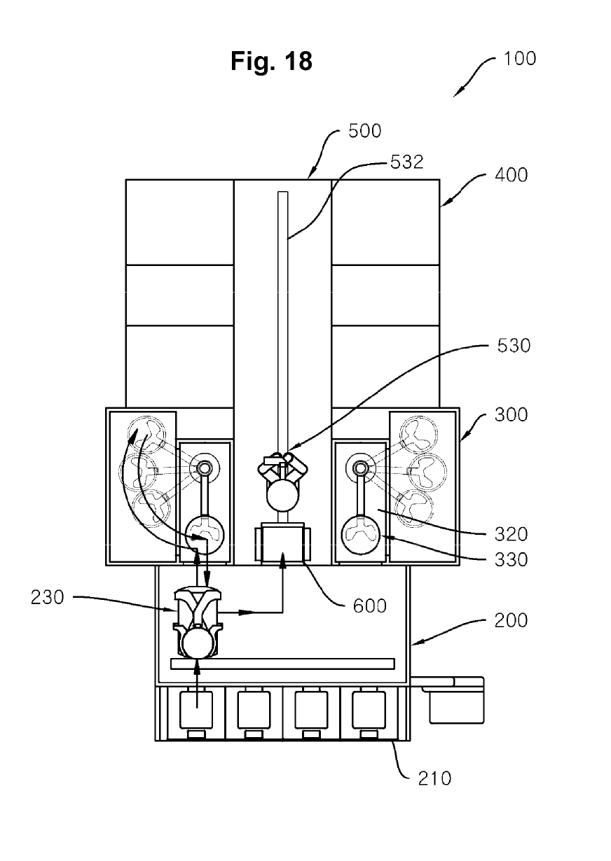

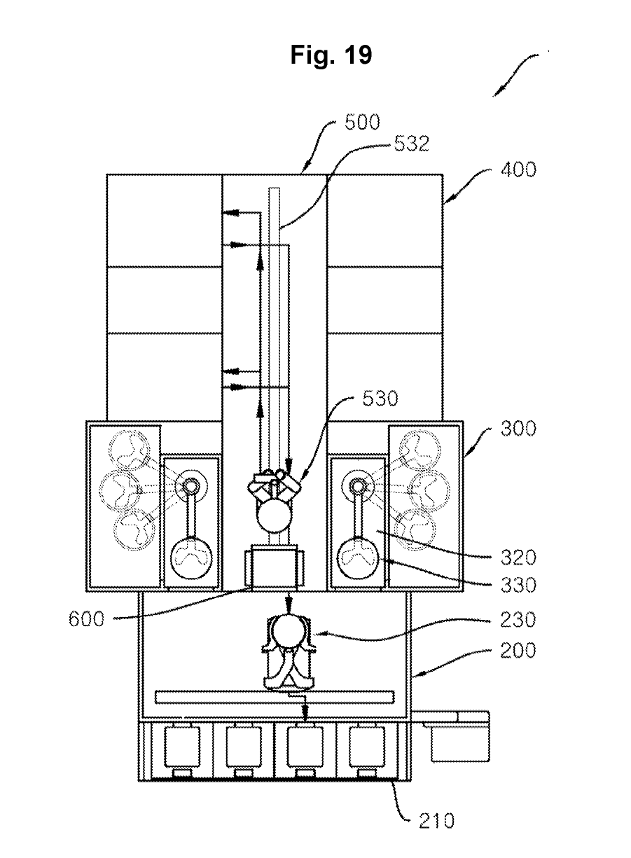

FIGS. 18 and 19 are views illustrating the path of substrate.

Description with reference to FIGS. 18 and 19 of a substrate treatment process is as follows.

First, using atmospheric pressure substrate transfer robot (230), the substrate (106) loaded in the cassette (210) is unloaded. At this time, atmospheric pressure substrate transfer robot (230) transfers the substrate by a vacuum system. Using atmospheric pressure substrate transfer robot (230), the substrate (106) is delivered to first substrate transfer robot (320) of dry processing module (300). At this time, First substrate carrying module (320) of dry processing module (300) is in a vacuum state as the atmospheric pressure substrate carrying module (200). Again, First substrate carrying module (320) is converted to a vacuum condition, and first substrate transfer robot (330) drives the drive shaft and provides the substrate (106) to the stage (302) within dry processing chamber (310). Dry-processed substrate (106) is again unloaded by first substrate transfer robot (330) of first substrate carrying module (320), and delivered to the atmospheric pressure substrate transfer robot (230) of the atmospheric pressure substrate carrying module (200). At this time, first substrate carrying module (320) is again in the state of atmospheric pressure. Atmospheric pressure substrate transfer robot (230) loads the dry-processed substrate (106) in a vacuum grip method to a cooling chamber (610) of buffer chamber (600). In the cooling chamber (610), using pusher unit (650), substrates (160) are aligned to the center in order to transfer the substrate (106) in the method of edge grip.

Second substrate transfer robot (530) moves along the rails (532) provided in second substrate transfer module (500) for loading/unloading the substrate to the wet processing module (400), and unloads the substrate (106) stacked on the cooling buffer (610) of the buffer chamber (600) in the way of edge grip. Each of unloaded substrates (106) is loaded to the wet processing module (400) via second substrate transfer robot (530) respectively and go through the wet process. Wet-treated substrate (106) is again unloaded through second substrate transfer robot (530) and stacked on the standby buffer (630) of buffer chamber (600). The substrate (106) stacked on the standby buffer (630) is unloaded through atmospheric pressure substrate transfer robot (230) and stacked on the cassette (210).

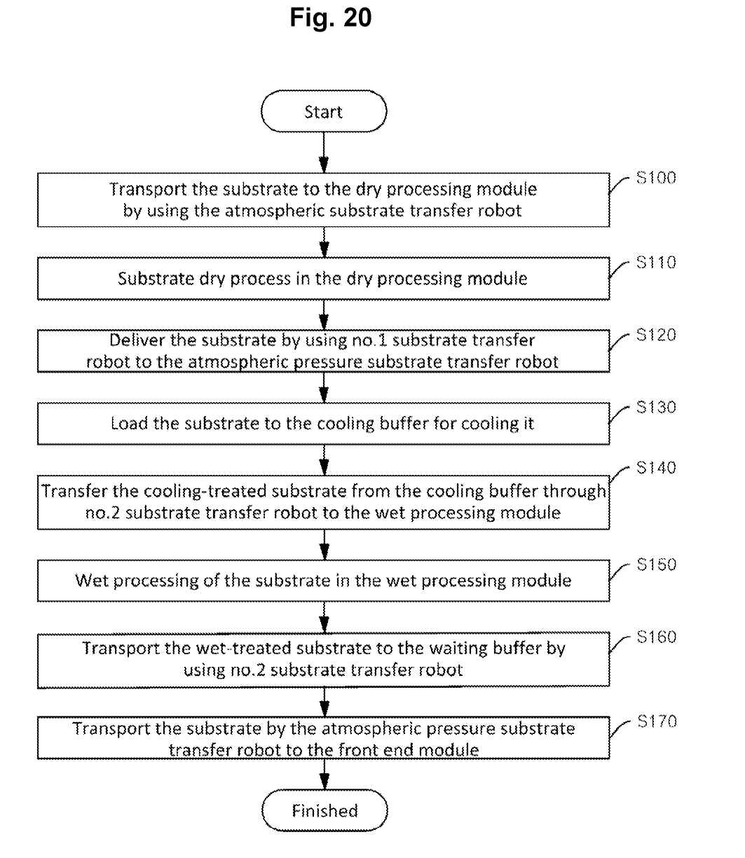

FIG. 20 is a flowchart illustrating the substrate dry-wet processing method using the substrate processing system of the present invention.

Referring to FIG. 20, the substrate (106) can go through a wet treatment process after going through a dry treatment processing, using the substrate treatment system (100). Using the atmospheric pressure substrate transfer robot (230) of atmospheric pressure substrate carrying module (200), the substrate is transferred to a dry processing module (300) (S100). The transferred substrate (106) is loaded through first substrate transfer robot (330) of dry processing module (300) to the dry processing module (300) and goes through the dry process (S110). The substrate (106), whose temperature is elevated through dry treatment, is again delivered to the Atmospheric pressure substrate carrying robot (230) through first substrate transfer robot (330) and transferred (S120) to the atmospheric pressure substrate carrying module (200). In the atmospheric pressure substrate carrying module (200), the substrate (106) is loaded to the cooling buffer (630) of the buffer chamber (600), using the atmospheric pressure substrate transfer robot (230) (S130). The substrate (106) is cooled by the water-cooling or air-cooling method within the cooling buffer (630). The substrate (106) cooled in the cooling buffer (630) is unloaded by second substrate transfer robot (530) of second substrate carrying module (500) and transferred to the wet processing module (400) (S140). The transferred substrate (106) is loaded to the wet processing module (400) and undergoes the wet treatment (S150). The substrate (106) with completed wet processing is again unloaded from the wet processing module (400) through second substrate transfer robot (530) and transferred to the standby buffer (610) of the buffer chamber (600). The substrate (106) stacked on the standby buffer (610) is transferred through the atmospheric pressure substrate transfer robot (230) of the atmospheric pressure substrate carrying module (200) and loaded on the cassette (210) (S170).

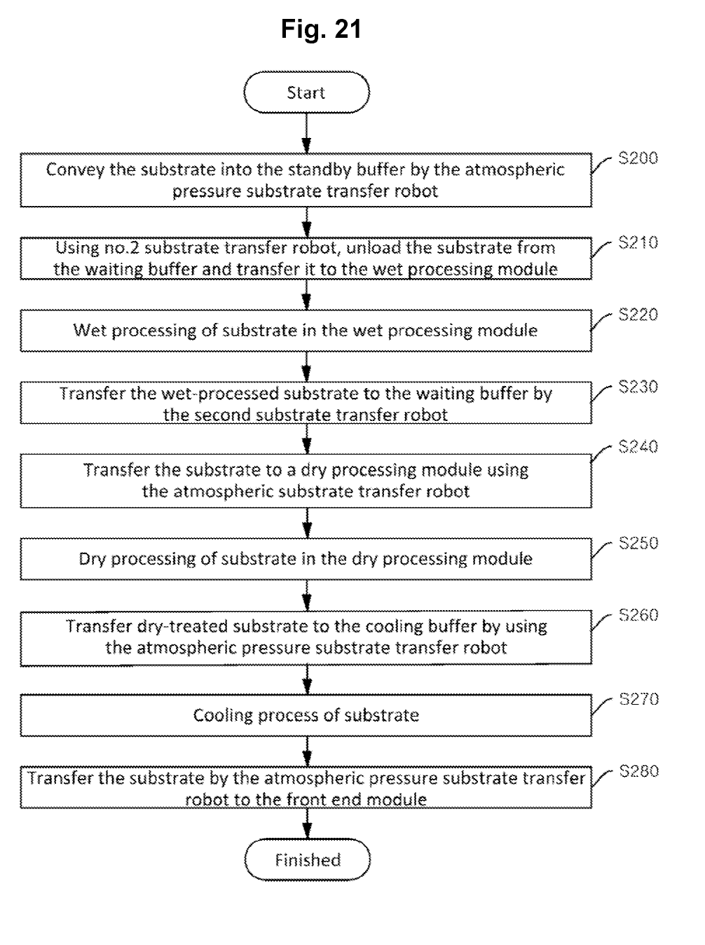

FIG. 21 is a flow chart illustrating the wet-dry processing method of the substrate using the substrate processing systems of the invention.

Referring to FIG. 21, the substrate (106) can go through a dry treatment process after going through a wet treatment processing, using the substrate treatment system (100). Using the atmospheric pressure substrate transfer robot (230) of atmospheric pressure substrate carrying module (200), the substrate is transferred to the standby buffer (620) of the buffer chamber (600) and loaded (S200). The substrate (106) loaded on the standby buffer (620) is unloaded through second substrate transfer robot (530) of second substrate carrying module (500) and loaded to wet processing module (400) (S210). In the wet processing module (400), the substrate (106) undergoes a wet process (S220). The wet-processed substrate is again transferred to the standby buffer (610) of buffer chamber (600) through second substrate transfer robot (530) (8230). The substrate (106) stacked on standby buffer (610) is unloaded through the atmospheric pressure substrate transfer robot (230) of the atmospheric pressure substrate carrying module (200), and delivered to first substrate transfer robot (330) and loaded to the dry processing module (300) (S240). The substrate (106) goes through the dry process in the dry processing module (300) (S250). Dry-treated substrate (106) is again unloaded by first substrate transfer robot (330) and transferred by atmospheric pressure substrate transfer robot (230) to the cooling buffer (630) of buffer chamber (600) (S260). The substrate (106) goes through cooling process in the cooling buffer (630) (S270). Cooling-treated substrate (106) is transferred via the atmospheric pressure substrate transfer robot (230) to the front end module (S280).

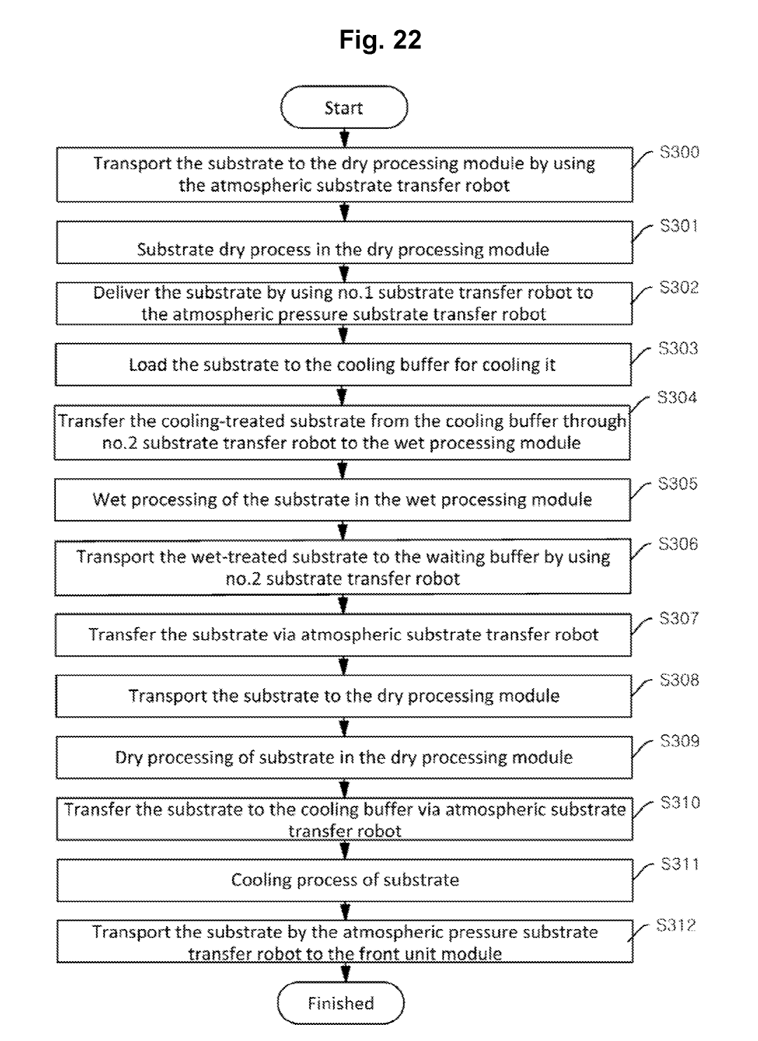

FIG. 22 is a flow chart illustrating the substrate dry-wet treatment method using the substrate processing system of the present invention.

Referring to FIG. 22, using a substrate processing system, a substrate can go through a dry treatment process and then a wet treatment process, and then again a dry treatment process. In the same manner shown in FIG. 20, substrate (106) goes through a dry process and a wet process. Using atmospheric pressure substrate transfer robot (230) of atmospheric pressure substrate transfer module (200), the substrate (106) is transferred to dry processing module (300) (8300). The transferred substrate (106) is loaded to a dry process module through first substrate transfer robot (330) of dry processing module (300) and undergoes the dry process (S301). The substrate (106), whose temperature is elevated through dry treatment, is again delivered to the atmospheric pressure substrate transfer robot (230) through first substrate transfer robot (330) (8302). In the atmospheric pressure substrate transfer module (200); the substrate (106) is loaded to the cooling buffer (630) of the buffer chamber (600), using the atmospheric pressure substrate transfer robot (230) (S303). The substrate (106) is cooled by the water-cooling or air-cooling method within the cooling buffer (630). The substrate (106) cooled in the cooling buffer (630) is unloaded by second substrate transfer robot (530) of second substrate carrying module (500), and transferred to the wet processing module (400) (S305). The transferred substrate (106) undergoes the wet treatment in wet processing module (400) (S306). The substrate (106) with completed wet processing is again unloaded from the wet processing module (400) through second substrate transfer robot (530) and transferred to the standby buffer (610) of the buffer chamber (600). The substrate (106) stacked on the standby buffer (610) is transferred through the atmospheric pressure substrate transfer robot (230) of the atmospheric pressure substrate carrying module (200) to the front end module (S308). The transferred substrate (106) is again transferred to dry processing module (400), and undergoes the dry process in the, dry processing module (300) (S309). Dry-treated substrate is transferred via atmospheric pressure substrate transfer robot (230, 330) to cooling buffer (630) (S310). The substrate (106) receives cooling process in the cooling buffer (630) (S311). The cooled substrate (106) is again unloaded via atmospheric pressure substrate transfer robot (230) and transferred to a cassette (210) of the front end module (S312).

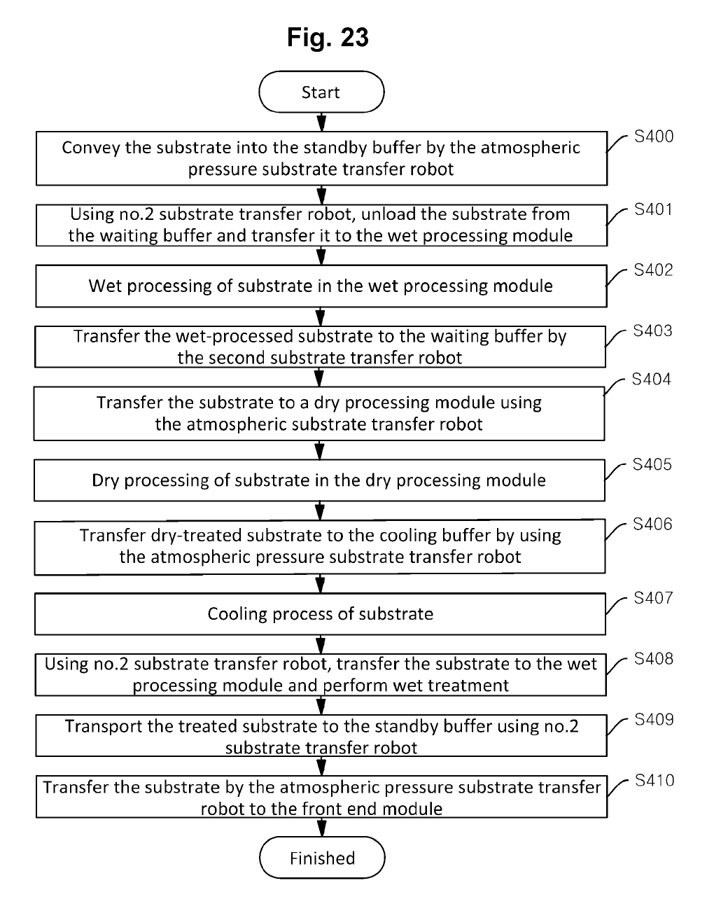

FIG. 23 is a flowchart illustrating the substrate wet-dry-wet processing method using the substrate processing system of the present invention.

Referring to FIG. 23, using the substrate processing system (100) the substrate (106) can go through a wet treatment process, and then a dry treatment process, and then again a wet treatment process. Using atmospheric pressure substrate transfer robot (230) of atmospheric carrying module (200), the substrate is transferred to standby buffer (610) of buffer chamber (600) and loaded (S400). The substrate (106) stacked on the standby buffer (610) is unloaded via second substrate transfer robot (530) of second substrate carrying module (500) and loaded to wet processing module (400) (S401). Through a spray nozzle provided in the wet processing module (400), it sprays DI Water (De-ionized water) or DI Ozone Chemicals (De-ionized Ozone chemicals) in the gas or vapor state to the central region of substrate (106), and performs the wet treatment (S402). It is an immersion step of pretreatment of impurities on the surface of the substrate (106). The wet-treated substrate (106) is again transferred via second substrate transfer robot (530) to the standby buffer (610) (S403). The substrate (106) stacked on standby buffer (610) is unloaded through atmospheric pressure substrate transfer robot (230) of the atmospheric pressure substrate carrying module (200), and delivered by atmospheric pressure substrate transfer robot (330) to first substrate transfer robot (330) and loaded to the dry processing module (330) (S404). In dry processing module (300), oxygen gas foaming process is performed as dry process. Oxygen gas foaming process is to increase the efficiency of impurity removal of substrate (106) in the next step, and carbide layer formed on the surface of substrate (106) is removed by oxygen gas (S405). Dry-treated substrate (106) is again unloaded by first substrate transfer robot (330) and via atmospheric pressure substrate transfer robot (230), is transferred to cooling buffer (630) of buffer chamber (600) (S406). In the cooling buffer (630), the substrate goes through cooling treatment (S407). The cooling-treated substrate is transferred to wet processing module (400) via second substrate carrying module (530) for wet reprocessing (S408). In the wet processing module (400), SC-1 or hydrogen fluoride (HF) is sprayed onto the surface of the substrate (106) through the rotating spray nozzle. The treated substrate (106) is dried and again transferred via second substrate carrying module (530) to standby buffer (610) of buffer chamber (600) (S409). Through atmospheric pressure substrate transfer robot (230), the substrate (106) is unloaded from the standby buffer (610) and transferred to the front end module (S410).

As described above, since the wet, dry treatment processes are carried out in a single platform, it is possible to save the manufacturing time of the product. In addition, it is possible to reduce the manufacturing cost by saving the production time.

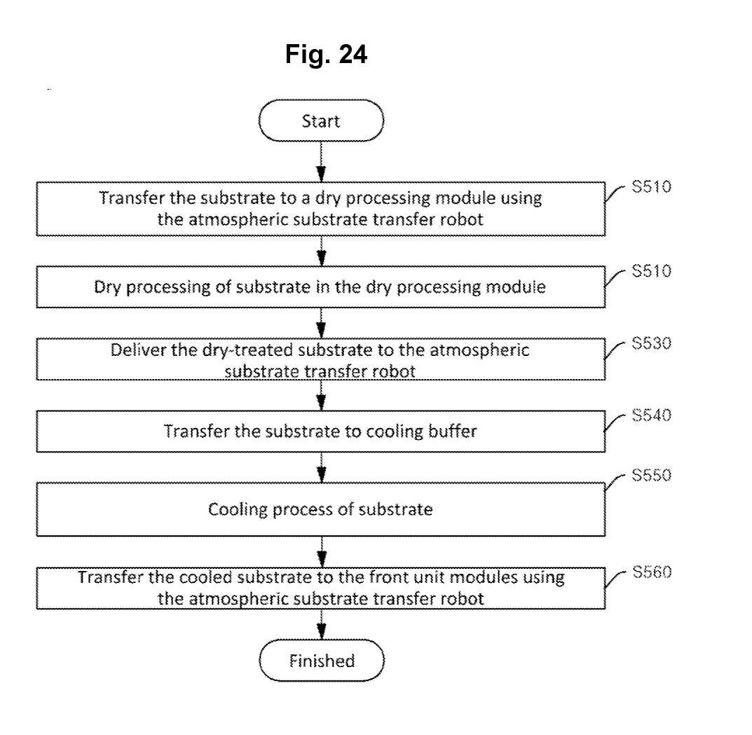

FIG. 24 is a flow chart illustrating a dry treatment method of a substrate using the substrate processing systems of the invention.

Referring to FIG. 24, only dry processing of the substrate can be carried out using the substrate processing system. The substrate (106), unloaded from the front end module using atmospheric pressure substrate transfer robot (230) of atmospheric carrying module (200) is transferred to first substrate transfer robot (330) of dry processing module (300) (S510). In the dry processing module (300), the substrate (106) goes through the dry process (S520). Dry-treated substrate (106) is transferred to atmospheric carrying module (200) via first substrate transfer robot (230) (S530). Dry-treated substrate (106) with high temperature is transferred (S540) via atmospheric pressure substrate transfer robot (230) to cooling buffer (630) and undergoes cooling process (S550), Cool-treated substrate (106) is again transferred to the front end module via atmospheric pressure substrate transfer robot (230) (S560).

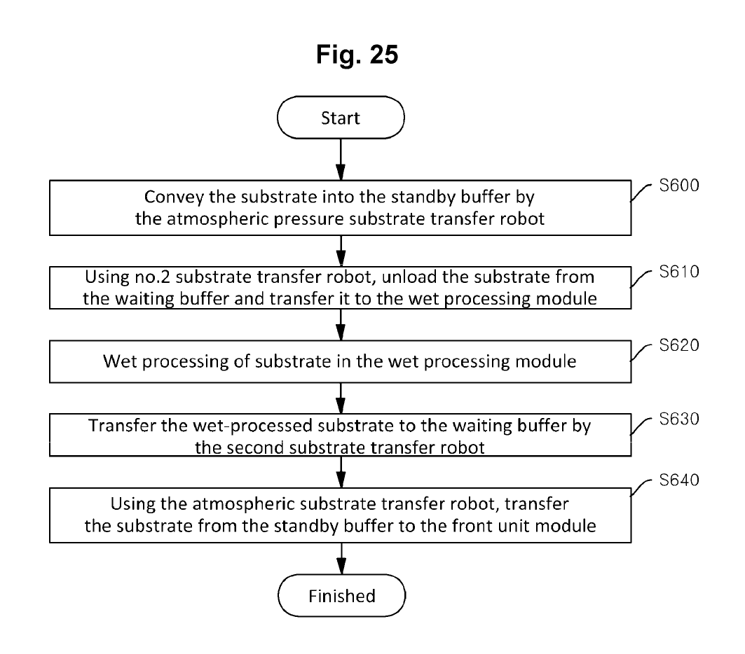

FIG. 25 is a flow chart illustrating a wet treatment method of a substrate using the substrate processing system of the invention.

Referring to FIG. 25, it may perform only the wet treatment process of the substrate by using the substrate processing system. Using atmospheric pressure substrate transfer robot (230) of atmospheric carrying module (200), the substrate (106) is transferred to standby buffer (610) of buffer (S600). Substrate (106) stacked on the waiting buffer (610) is unloaded through second substrate transfer robot (530) and transferred to wet processing module (400) (S610). The transferred substrate (106) receives wet treatment in the wet processing module (400) (S620). The substrate (106) with completed wet processing is again transferred to the standby buffer (610) of buffer by using second substrate transfer robot (530) (S630). Using atmospheric pressure substrate transfer robot (230), the substrate (106) stacked on the standby buffer (610) is unloaded and transferred to the front end module (S640).

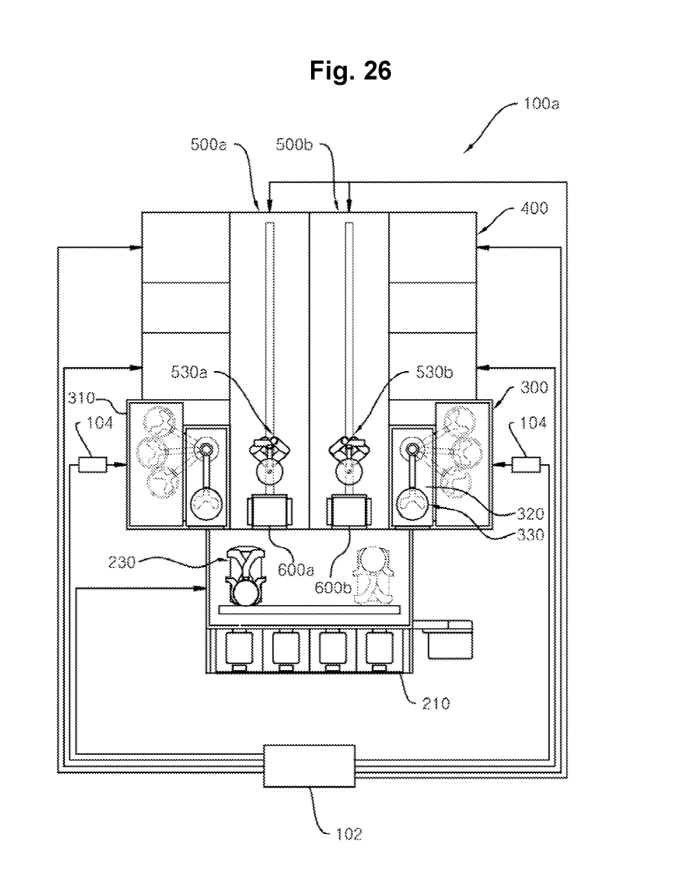

FIG. 26 is a view illustrating the structure of a hybrid substrate processing system according to the second preferred embodiment of the present invention.

Referring to FIG. 26, the substrate processing system (100a) is provided with two second substrate carrying modules (500a, 500b). Each of the second substrate carrying modules (500a, 500b) is equipped with second substrate transfer robot (530). Second substrate carrying modules (500a, 500b) are connected to two buffer chambers (600a, 600b) respectively. It can also utilize a single buffer chamber. The two third substrate transfer modules (500a, 500b) distribute and transfer the substrate (106) loaded/unloaded to a plurality of wet treatment module (400). Therefore, the loading/unloading time of substrate to the wet processing module (400) is shortened. The remaining configuration of the substrate processing system (100a) is the same as described above.

The hybrid substrate processing system for dry process and wet process of the present invention and examples of embodiment of the substrate processing method thereof described above are merely illustrative, and any person with common knowledge in the technological field to which the present invention belongs will be well understood that from this, various modifications and equivalent other embodiments are possible.

Therefore, the present invention will be well understood as not limited to the form referred to in the detailed description above. Therefore, the true technical protection scope of the present invention shall be defined by the technical spirit of the appended claims. Also, the present invention shall be understood to include all modifications and equivalents and alternatives falling within the spirit and scope of the invention as defined by the appended claims.

### DESCRIPTION OF SYMBOLS

100, 100a: Substrate processing system
102: Controller
104: Vacuum pumps
106: Substrate/Board
200: Atmospheric pressure carrying module
210: Cassette
230: Atmospheric pressure substrate transfer robot
231: First Body parts
232: Second Body parts
240: Rail
242: Track
252: First transfer arm
254: Moving Guide
256: Edge grip end effector
257: Second transfer arm
258: Vacuum grip end effector
259: Substrate Position Sensor
300: Dry processing module
302: Stage
310: Dry processing chamber
320: First substrate carrying module
330: First substrate transfer robot
332: Drive shaft
334: Transfer arm
336: End effector
400: Wet processing module
500: Second substrate carrying module
530,530a,530b: Second substrate transfer robot
532: Rail
534: Transfer arm
600: Buffer chamber
602: Exhaust box
610: Standby buffer
620: Standby buffer slot
622, 624: First and second standby buffer slot
625: Limit
627: Substrate loader
630: Cooling buffer
632: Bottom surface
633, 637: Opening
636: Side
638: Vent
640: Cooling buffer slot
642,644: First and second Cooling buffer slot
645: Limit
646 Substrate support member
647: Bump
650: Pusher unit
652, 653: First and second Body parts
654: Push bar
661: Coolant Inlet
663: Cooling path
664: Coolant outlet

1. A Hybrid substrate processing system for dry and wet process and substrate processing method thereof comprises of:
a front end module where the board is waiting;
an atmospheric pressure carrying module for loading/unloading the substrate wherein the front end module;
one or more dry processing modules for the dry processing the substrate loaded from the atmospheric pressure carrying module;
one or more wet processing module for wet processing the substrate;
the buffer chamber in which the cooling-treated or loaded substrate is waiting;
an atmospheric pressure substrate transfer robot that is provided the atmospheric pressure carrying module, for transferring the substrate between the said buffer chamber and the dry-processing module;
first substrate carrying module provided with first substrate transfer robot for exchanging the substrate with the atmospheric pressure substrate transfer robot and for loading/unloading the substrate to/from the dry-processing module; and
second substrate carrying module provided with second substrate transfer robot for loading/unloading the substrate to/from the buffer chamber, and loading/unloading the substrate to/from the said wet processing module.

2. The hybrid substrate processing system of claim 1, wherein the dry processing module comprises a removing the carbide layer of photoresist formed on the substrate surface during the ion implantation process, by being equipped with plasma source and performing the ashing process wherein the substrate.

3. The hybrid substrate processing system of claim 1, further comprises a controller that controls the operation of the dry processing module and the wet processing module, and controls the operation of the atmospheric pressure substrate transfer robot and the first and second substrate transfer robot for transfer of the substrate.

4. The hybrid substrate processing system of claim 1, wherein the first substrate transfer robot comprises a plurality of transfer arms;
the rotation shaft for rotating the transfer arm; and
an end effector in which the said substrate is mounted by being connected to the end of the transfer arm.

5. The hybrid substrate processing system of claim 4, wherein the dry processing module comprises a plurality of stages that are arranged on the pivoting path of the transfer arm of the first substrate transfer robot.

6. The hybrid substrate processing system of claim 1, wherein the buffer chamber comprises a cooling buffer provided with a plurality of cooling buffer slots; and
a standby buffer equipped with a plurality of standby buffer slots for mounting substrates.

7. The hybrid substrate processing system of claim 6, wherein the cooling buffer slots comprise of:
a first cooling buffer slot equipped with the support member for supporting wherein the substrate; and
a second cooling buffer slot equipped with the limit in contact with the substrate.

8. The hybrid substrate processing system of claim 6, wherein the cooling buffer or standby buffer comprises a plurality of pusher units for the centered alignment of the substrate.

9. The hybrid substrate processing system of claim 1, wherein the atmospheric pressure substrate transfer robot comprises a plurality of transfer arms to be installed to enable linear movement;
a plurality of edge grip end effectors for transferring a substrate in an edge grip method by being installed in the first group among the plurality of transfer arms; and
a plurality of vacuum grip end effectors for transferring a substrate in a vacuum grip method by being installed in the second group among the plurality of transfer arms.

10. The hybrid substrate processing system of claim 1, wherein the wet treatment module comprises one or more spray nozzles for spraying de-ionized water or cleaning agent in a gas or vapor state.

11. A hybrid substrate processing system comprising:
unloading the substrate from the front end module and transferring the substrate to the first substrate carrying module by using the atmospheric pressure substrate transfer robot;
treating a dry processing after loading the substrate to the dry process module by using the first substrate transfer robot of the first substrate carrying module;
delivering the dry-processed substrate from the dry-processing module to the atmospheric pressure carrying robot by the first substrate transfer robot;
transferring the substrate to a cooling chamber of the buffer chamber with the atmospheric pressure carrying robot; and
unloading the substrate from the said cooling chamber and transferring the substrate to the front end module using the atmospheric pressure carrying robot.

12. The method of claim 11, unloading the substrate using second substrate transfer robot of Second substrate carrying module from the cooling chamber;
treating a wet processing by loading the substrate to a wet processing module using second substrate transfer robot; and
loading the wet-processed substrate from the wet processing module to the standby chamber of the buffer chamber by using second substrate transfer robot.

13. The method of claim 12, unloading the substrate from the standby chamber to the first substrate carrying module by using the atmospheric pressure carrying robot;
loading the substrate to the dry process module using the first substrate transfer robot;
transferring the dry-processed substrates to the atmospheric pressure carrying robot by using the first transfer robot;
loading the substrate to the cooling chamber of the buffer chamber with the atmospheric pressure carrying robot; and
unloading the substrate from the cooling chamber by using the atmospheric pressure carrying robot and transferring the substrate to the front end module.

14. A hybrid substrate processing system comprising:
unloading the substrate from the front end module and loading it to the standby buffer of the buffer chamber by the atmospheric pressure substrate transfer robot;
unloading the substrate from the standby buffer using the second substrate transfer robot of the second substrate carrying module;
loading the substrate using the second substrate transfer robot to the wet processing module and performing the wet treatment;
loading the wet-treated substrate from the wet processing module using the second substrate transfer robot to the said standby buffer; and
unloading the substrate from the said standby buffer using the atmospheric pressure substrate transfer robot and conveying it to the front end module.

15. The method of claim 14, unloading the substrate from the waiting buffer using the atmospheric pressure carrying robot and delivering it to the first substrate transfer robot of the first substrate carrying module;
treating a dry processing after loading the substrate to a dry processing module using the first substrate transfer robot;
delivering the dry-processed substrate from the dry processing module to the atmospheric pressure carrying robot using the first substrate transfer robot;
transferring the substrate to a cooling chamber of the buffer chamber with the atmospheric pressure carrying robot; and
unloading the substrate from the cooling chamber and transferring it to the front end module by using the atmospheric pressure carrying robot.

16. The method of claim 15, treating a wet cleaning after unloading the substrate from the cooling chamber by the substrate transfer robot and transferring it to the wet treatment module;
transferring the wet-processed substrate to the standby buffer of the buffer chamber using second substrate transfer robot; and
unloading the substrate from the standby chamber using the Atmospheric carrying robot and conveying it to the front end module.
